(19) United States
(12) Patent Application Publication
(10) Pub. No.: US 2026/0172031 A1
(43) Pub. Date: Jun. 18, 2026

(54) MONITORING MULTIPLE SEQUENTIAL SIGNALS ON A SINGLE OBSERVATION PAD

(71) Applicant: QUALCOMM Incorporated, San Diego, CA (US)

(72) Inventors: Yuxin LI, San Diego, CA (US); Asha CHANNAMALLA SWAMY, San Diego, CA (US); Vikas MAHENDIYAN, Poway, CA (US)

(21) Appl. No.: 18/980,737

(22) Filed: Dec. 13, 2024

(51) Int. Cl. H03K 19/00; H03K 19/20

(52) U.S. Cl. CPC H03K 19/0002; H03K 19/20

(57) ABSTRACT

A chip includes a first modulator configured to receive a first internal signal, and convert the first internal signal into a first output signal including a first pattern, and a second modulator configured to receive a second internal signal, and convert the second internal signal into a second output signal including a second pattern distinct from the first pattern. The chip also includes an observation pad, and a merge circuit coupled to the observation pad, wherein the merge circuit is configured to merge the first output signal and the second output signal into a merged output signal, and output the merged output signal to the observation pad, wherein the merged output signal includes the first pattern and the second pattern, and the first pattern and the second pattern are spaced apart in the merged output signal.

### BACKGROUND

### Field

Aspects of the present disclosure relate generally to monitoring signals, and more particularly, to monitoring multiple signals on a pad.

### Background

In many cases, it is desirable to observe internal signals in a chip to verify that one or more circuits integrated on the chip are functioning properly and/or meeting a timing specification. The internal signals may be observed by routing the internal signals to one or more observation pads on the chip, which output the internal signals off chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first modulator configured to receive a first internal signal, and convert the first internal signal into a first output signal including a first pattern, and a second modulator configured to receive a second internal signal, and convert the second internal signal into a second output signal including a second pattern distinct from the first pattern. The chip also includes an observation pad, and a merge circuit coupled to the observation pad, wherein the merge circuit is configured to merge the first output signal and the second output signal into a merged output signal, and output the merged output signal to the observation pad, wherein the merged output signal includes the first pattern and the second pattern, and the first pattern and the second pattern are spaced apart in the merged output signal.

A second aspect relates to a chip. The chip includes an observation pad and a merge circuit coupled to the observation pad. The merge circuit includes a pulse generator configured to receive a first internal signal and a second internal signal, and generate a pulse having a width approximately equal to a timing gap between a first edge in the first internal signal and a second edge in the second internal signal.

A third aspect relates to a method for signal monitoring. The method includes receiving a first internal signal in a chip, converting the first internal signal into a first output signal including a first pattern, receiving a second internal signal in the chip, and converting the second internal signal into a second output signal including a second pattern distinct from the first pattern. The method also includes merging the first output signal and the second output signal into a merged output signal, wherein the merged output signal includes the first pattern and the second pattern, and the first pattern and the second pattern are spaced apart in the merged output signal. The method further includes outputting the merged output signal to an observation pad on the chip.

### BRIEF DESCRIPTION OF THE DRAWINGS

FIG. 1 shows an example of multiplexers where each of the multiplexers is configured to selectively couple a functional signal or an internal signal to a respective pad according to certain aspects of the present disclosure.

FIG. 2 shows an example of observation pads on a chip for enabling observation of internal signals in the chip according to certain aspects of the present disclosure.

FIG. 3 shows an example in which a chip includes modulators and a merge circuit for observing multiple events from an observation pad according to certain aspects of the present disclosure.

FIG. 4 is a timing diagram illustrating an example in which internal signals indicative of events on the chip are converted into patterns by the modulators in FIG. 3 according to certain aspects of the present disclosure.

FIG. 5 shows an example of a chip including the modulators, the merge circuit, a first circuit, a second circuit, and a third circuit according to certain aspects of the present disclosure.

FIG. 6 shows an example in which the modulators in FIG. 5 are omitted according to certain aspects of the present disclosure.

FIG. 7 shows an example in which the merge circuit includes a pulse generator according to certain aspects of the present disclosure.

FIG. 8 is a timing diagram illustrating an example in which the pulse generator generates a pulse having a width indicative of a timing gap between a first event and a second event according to certain aspects of the present disclosure.

FIG. 9 shows an example in which the merge circuit also includes merge logic for merging the pulse generated by the pulse generator with an internal signal indicative of a third event.

FIG. 10 is a timing diagram illustrating an example in which the pulse from the pulse generator is merged with the internal signal indicative of the third event according to certain aspects of the present disclosure.

FIG. 11 shows an example of a memory interface in which aspects of the present disclosure may be used.

FIG. 12 shows an example in which the merge circuit and the observation pad are used to monitor a first enable signal, a second enable signal, and a qualifier signal in the memory interface according to certain aspects of the present disclosure.

FIG. 13 is a timing diagram illustrating an example of the first enable signal, the second enable signal, and the qualifier signal according to certain aspects of the present disclosure.

FIG. 14 is a flowchart illustrating a method for signal monitoring according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

In many cases, it is desirable to observe internal signals in a chip to verify that circuits integrated on the chip are functioning properly and/or meeting a timing specification. The internal signals may be routed to one or more pads on the chip, which output the internal signals off chip. This provides a test system coupled to the one or more pads with access to the internal signals for testing purposes. As used herein, an “internal signal” is a signal that is used internally in the chip and which may be accessed externally via a pad on the chip (e.g., for testing purposes).

For example, each of the internal signals may indicate a respective event in the chip. In this example, the internal signals may be observed to determine whether a timing relationship of the events meet a timing specification. The internal signals may include one or more enable signals, one or more qualifier signals, and/or one or more other internal signals in the chip. An event indicated by an internal signal may include enablement of a circuit on the chip, input of the internal signal to a circuit on the chip, etc. For the example in which an internal signal is indicative of an event in the chip, the internal signal may also be referred to as an event signal.

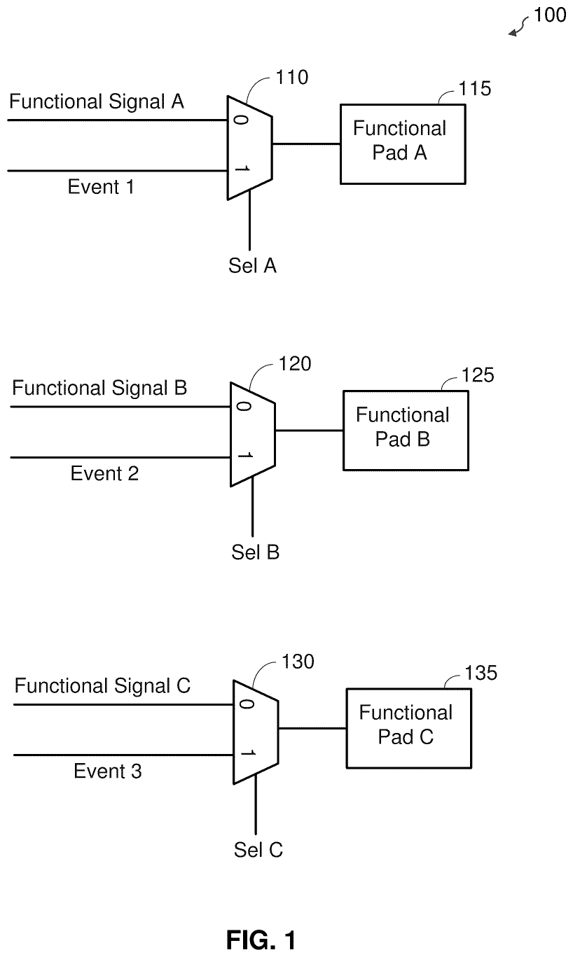

FIG. 1 illustrates a first approach for observing internal signals on a chip 100 according to certain aspects. For example, the internal signals may be indicative of events in one or more circuits (not shown) on the chip 100. The one or more circuits may also be referred to as one or more on-chip circuits or one or more integrated circuits. In this example, the internal signals may be observed to determine whether a timing relationship of the events meet a timing specification.

In the example shown in FIG. 1, the chip 100 includes a first multiplexer 110, a second multiplexer 120, a third multiplexer 130, a first functional pad 115, a second functional pad 125, and a third functional pad 135. The functional pads 115, 125, and 135 may be coupled to one or more external circuits (not shown) for sending signals from the chip 100 to the one or more external circuits.

The first multiplexer 110 has an output coupled to the first functional pad 115. The first multiplexer 110 is configured to receive a first functional signal (labeled “Functional Signal A”) from the one or more on-chip circuits and a first internal signal indicative of a first event (labeled “Event 1”) in the one or more on-chip circuits. The first functional signal may include a data signal, a timing signal, and/or a control signal that is sent from the one or more on-chip circuits to one or more external circuits (e.g., on another chip). The first multiplexer 110 is configured to select the first functional signal or the first internal signal based on a first select signal (labeled “Sel A”) and output the selected one of the first functional signal or the first internal signal to the first functional pad 115 for output off the chip 100. For example, the first multiplexer 110 may select the first functional signal when the first select signal has a logic value of zero and select the first internal signal when the first select signal has a logic value of one.

The second multiplexer 120 has an output coupled to the second functional pad 125. The second multiplexer 120 is configured to receive a second functional signal (labeled “Functional Signal B”) from the one or more on-chip circuits and a second internal signal indicative of a second event (labeled “Event 2”) in the one or more on-chip circuits. The second functional signal may include a data signal, a timing signal, and/or a control signal. The second multiplexer 120 is configured to select the second functional signal or the second internal signal based on a second select signal (labeled “Sel B”) and output the selected one of the second functional signal or the second internal signal to the second functional pad 125 for output off the chip 100. For example, the second multiplexer 120 may select the second functional signal when the second select signal has a logic value of zero and select the second internal signal when the second select signal has a logic value of one.

The third multiplexer 130 has an output coupled to the third functional pad 135. The third multiplexer 130 is configured to receive a third functional signal (labeled “Functional Signal C”) from the one or more on-chip circuits and a third internal signal indicative of a third event (labeled “Event 3”) in the one or more on-chip circuits. The third functional signal may include a data signal, a timing signal, and/or a control signal. The third multiplexer 130 is configured to select the third functional signal or the third internal signal based on a third select signal (labeled “Sel C”) and output the selected one of the third functional signal or the third internal signal to the third functional pad 135 for output off the chip 100. For example, the third multiplexer 130 may select the third functional signal when the third select signal has a logic value of zero and select the third internal signal when the third select signal has a logic value of one.

In some implementations, the first select signal, the second select signal, and the third select signal may be the same (i.e., the multiplexers 110, 120, and 130 may be controlled by the same select signal). In these implementations, the multiplexers 110, 120, and 130 may select the respective functional signals in a functional mode or select the respective internal signals in an observation mode based on the select signal.

Thus, the first approach illustrated in FIG. 1 allows multiple events in the one or more on-chip circuits to be observed using the functional pads 115, 125, and 135. In other words, the functional pads 115, 125, and 135 are capable of outputting either functional signals or internal signals (e.g., event signals) off chip. When the multiplexers 110, 120, and 130 select the respective internal signals, the timing of the corresponding events can be observed using the respective internal signals. However, a drawback of this approach is that the events cannot be observed without affecting the functional outputs (i.e., the chip 100 cannot output the functional signals while the events are being observed).

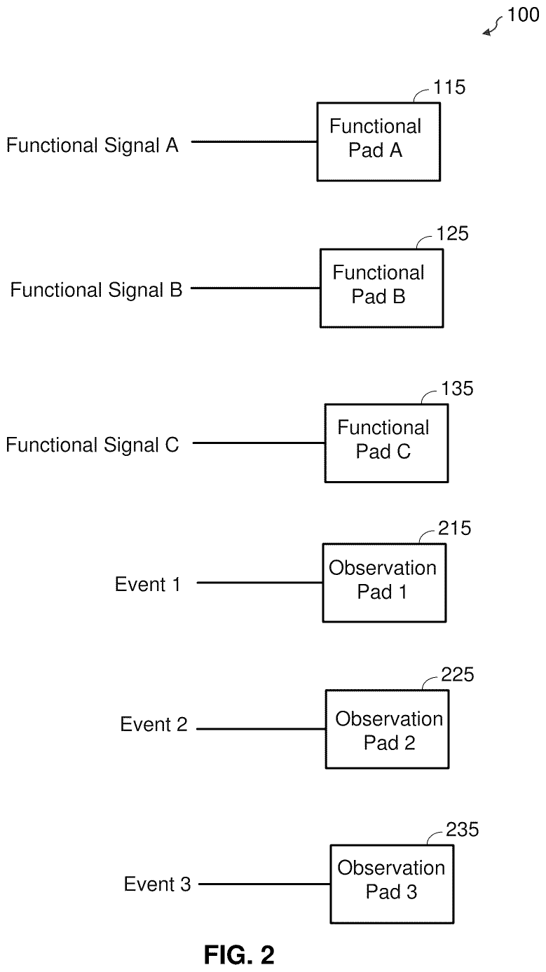

FIG. 2 illustrates a second approach in which the chip 100 includes additional pads for the internal signals including a first observation pad 215, a second observation pad 225, and a third observation pad 235. In this example, the functional signals and the internal signals (e.g., event signals) are output from separate pads. The first internal signal indicative of the first event is output from the first observation pad 215, the second internal signal indicative of the second event is output from the second observation pad 225, and the third internal signal indicative of the third event is output from the third observation pad 235. Also, the first functional signal is output from the first functional pad 115, the second functional signal is output from the second functional pad 125, and the third functional signal is output from the third functional pad 135. The separate pads allow the events to be observed using the internal signals while the chip 100 outputs the functional signals. In other words, the functional outputs do not need to be stopped to observe the events. However, adding the observation pads 215, 225, and 235 can be costly and the chip 100 may not have enough room for the additional pads.

To address the above, aspects of the present disclosure allow multiple internal signals (e.g., event signals) in a chip to be output from a single pad by merging the internal signals into a merged signal and outputting the merged signal from the pad. This reduces the number of pads compared with providing a separate pad for each of the internal signals. In certain aspects, the pad is separate from pads on the chip used to output functional signals. This allows a sequence of multiple events to be observed without the need to stop the output of the functional signals. The above features and other features of the present disclosure are discussed further below.

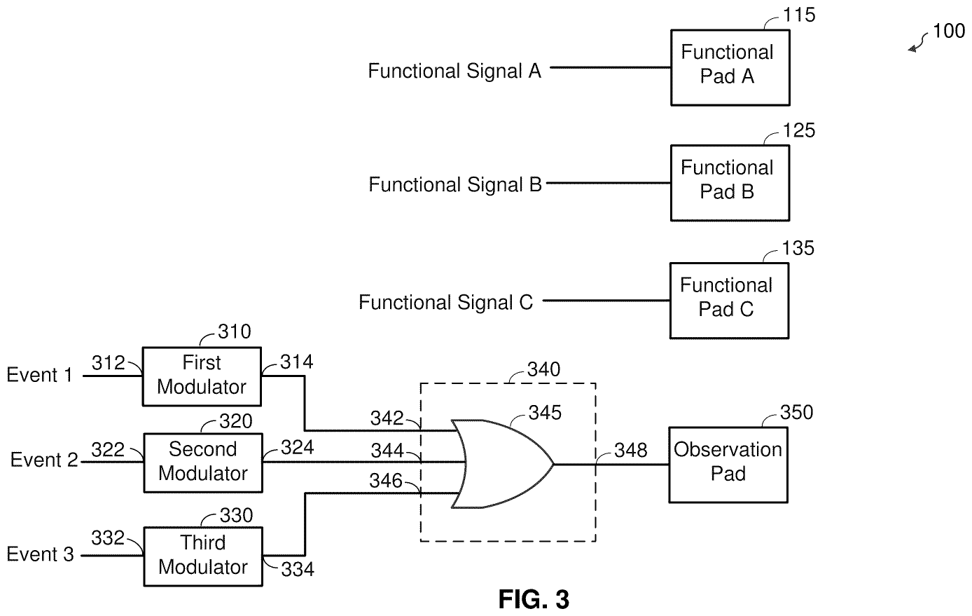

FIG. 3 shows an example of the chip 100 according to certain aspects. In this example, the chip 100 includes the functional pads 115, 125, and 135 discussed above. The chip 100 also includes an observation pad 350, a first modulator 310, a second modulator 320, a third modulator 330, and a merge circuit 340.

In this example, the first modulator 310 has an input 312 and an output 314. The input 312 is configured to receive the first internal signal indicative of the first event, and the output 314 is coupled to a first input 342 of the merge circuit 340. The first modulator 310 is configured to convert the first internal signal into a first output signal including a first pattern. As discussed further below, the first pattern allows the first output signal to be distinguished from other signals.

The second modulator 320 has an input 322 and an output 324. The input 322 is configured to receive the second internal signal indicative of the second event, and the output 324 is coupled to a second input 344 of the merge circuit 340. The second modulator 320 is configured to convert the second internal signal into a second output signal including a second pattern that is distinct from the first pattern. The distinct patterns of the first output signal and the second output signal allow the first output signal and the second output signal to be distinguished from one another.

The third modulator 330 has an input 332 and an output 334. The input 332 is configured to receive the third internal signal indicative of the third event, and the output 334 is coupled to a third input 346 of the merge circuit 340. The third modulator 330 is configured to convert the third internal signal into a third output signal including a third pattern that is distinct from the first pattern and the second pattern. The distinct patterns of the first output signal, the second output signal, and the third output signal allow the first output signal, the second output signal, and the third output signal to be distinguished from one another. In certain aspects, each of the patterns may include a distinct sequence of ones and zeros.

The merge circuit 340 has an output 348 coupled to the observation pad 350. The merge circuit 340 receives the first output signal from the first modulator 310 at the first input 342, receives the second output signal from the second modulator 320 at the second input 344, and receives the third output signal from the third modulator 330 at the third input 346. The merge circuit 340 is configured to merge the first output signal, the second output signal, and the third output signal into a merged output signal and output the merged output signal to the observation pad 350 for output off the chip 100. In the example shown in FIG. 3, the merge circuit 340 includes an OR gate 345. However, it is to be appreciated that the merge circuit 340 is not limited to this example. The merge circuit 340 may be implemented with any logic gate or combination of logic gates configured to merge the output signals from the modulators 310, 320, and 330 into the merged output signal. The merged output signal includes the patterns from the modulators 310, 320, and 330.

The merged output signal allows the first event, the second event, and the third event to be observed from the observation pad 350 instead of multiple observation pads (e.g., observation pads 215, 225, and 235 in FIG. 2). This reduces the number of pads on the chip 100 compared with providing a separate pad for each of the internal signals. Also, the observation pad 350 is separate from the functional pads 115, 125, and 135. This allows for efficient observation (i.e., monitoring) of the first event, the second event, and the third event without altering the paths of the functional pads 115, 125, and 135.

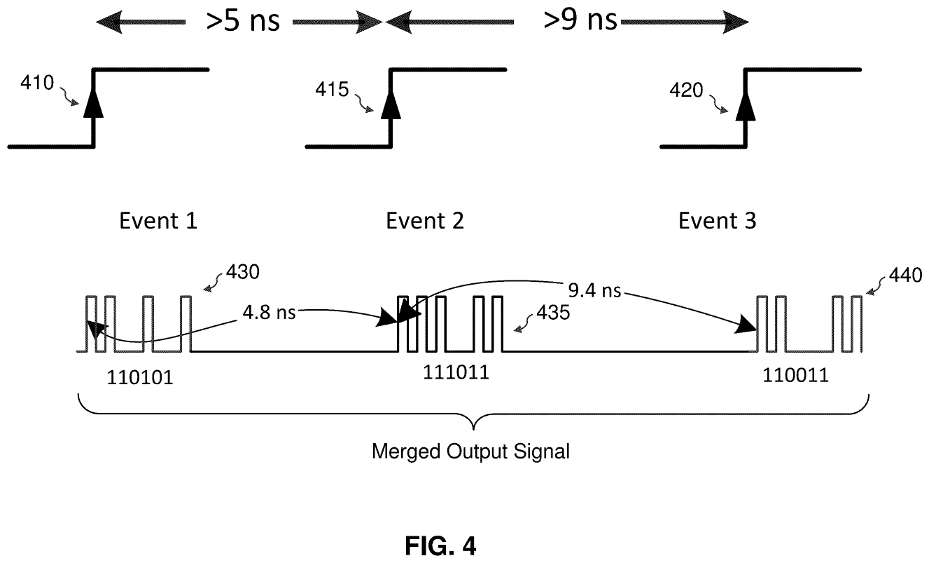

FIG. 4 is a timing diagram showing an example of the internal signals and the output signals from the modulators 310, 320, and 330 according to certain aspects. In this example, the first internal signal has a rising edge 410 indicating the first event, the second internal signal has a rising edge 415 indicating the second event, and the third internal signal has a rising edge 420 indicating the third event. However, it is to be appreciated that the present disclosure is not limited to this example. For example, in other implementations, an internal signal may have a falling edge indicating the respective event.

In this example, the first modulator 310 converts the rising edge 410 of the first internal signal into the first pattern 430 at the output 314 of the first modulator 310, the second modulator 320 converts the rising edge 415 of the second internal signal into the second pattern 435 at the output 324 of the second modulator 320, and the third modulator 330 converts the rising edge 420 of the third internal signal into the third pattern 440 at the output 334 of the third modulator 330. In the example shown in FIG. 4, each of the patterns 430, 435, and 440 includes a unique sequence of ones and zeros where a one corresponds to a pulse.

FIG. 4 shows an example of the merged output signal in which the merge circuit 340 merges the outputs signals from the modulators 310, 320, and 330 using an OR operation. In this example, the merged output signal at the output 348 of the merge circuit 340 includes the patterns 430, 435, and 440. In the example in FIG. 4, the timing gaps between the events cause the patterns 430, 435, and 440 in the merged output signal to be spaced apart, as shown in FIG. 4. As used herein, the term “spaced apart” means that the patterns are spaced apart from one another in time (i.e., temporally separated) in the merged output signal. This assumes that the length of the first pattern 430 is less than the timing gap between the first event (e.g., beginning of the first pattern 430) and the second event (e.g., beginning of the second pattern 435), and the length of the second pattern 435 is less than the timing gap between the second event (e.g., beginning of the second pattern 435) and the third event (e.g., beginning of the third pattern 440). The temporal separation of the patterns 430, 435, and 440 allow the patterns 430, 435, and 440 in the merged output signal to be distinguished from one another. Since each of the patterns 430, 435, and 440 corresponds to a respective one of the internal signals, each of the patterns 430, 435, and 440 indicates the event corresponding to the respective one of the internal signals. As a result, the patterns 430, 435, and 440 in the merged output signal allow the timing of each of the events to be determined based on the timing of the patterns 430, 435, and 440 in the merged output signal.

The timing of the patterns 430, 435, and 440 in the merged output signal may be used, for example, to determine whether the chip 100 meets a timing specification. In this regard, FIG. 4 shows an example in which the timing specification requires that the timing gap between the first event and the second event be greater than 5 ns and the timing gap between the second event and the third event be greater than 9 ns. In this example, the timing gap between the first pattern 430 (which is indicative of the first event) and the second pattern 435 (which is indicative of the second event) is 4.8 ns, which violates the minimum timing gap between the first event and the second event of 5 ns. Also, in this example, the timing gap between the second pattern 435 (which is indicative of the second event) and the third pattern 440 (which is indicative of the third event) is 9.4 ns, which complies with the minimum timing gap between the second event and the third event of 9 ns. It is to be appreciated that the timing specification is not limited to the exemplary timing requirements shown in FIG. 4. Rather, the exemplary timing requirements are intended to illustrate one example in which the patterns 430, 435, and 440 in the merged output signal may be used to check for compliance with the timing specification. The check may be performed, for example, by an external test system (not shown) coupled to the observation pad 350 in which the system is configured to capture the merged output signal and analyze the captured merged output signal to check for compliance with the timing specification.

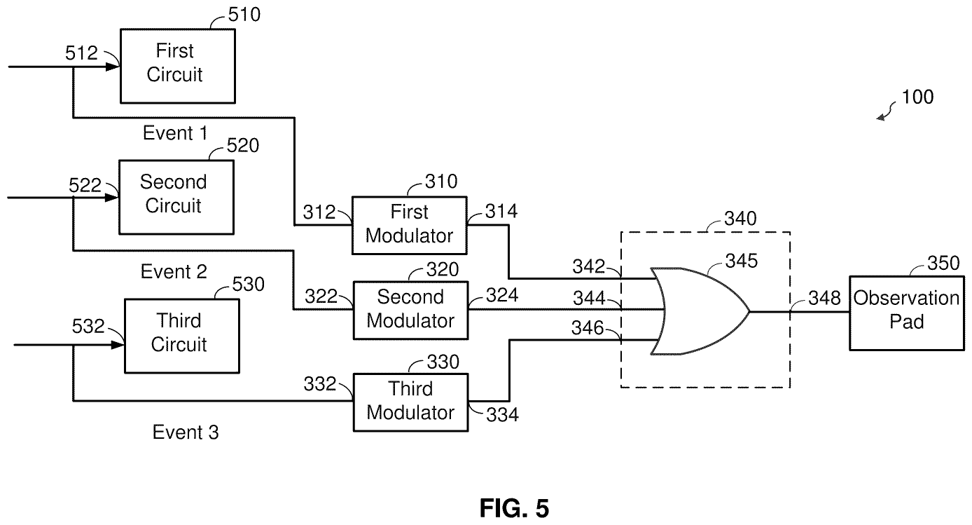

FIG. 5 shows an example in which the one or more circuits on the chip 100 include a first circuit 510, a second circuit 520, and a third circuit 530. Each of the circuits 510, 520, 530 may include a flip-flop, one or more logic gates, a receiver, a driver, etc. In this example, each of the events being observed may correspond to an event at a respective one of the circuits 510, 520, and 630.

In the example shown in FIG. 5, the first circuit 510 has an input 512 configured to receive the first internal signal. The first internal signal may include a respective enable signal for selectively enabling the first circuit 510, a respective qualifier signal, or another type of signal. For the example of the respective enable signal, the first event may correspond to enablement of the first circuit 510. For the example of the respective qualifier signal, the first event may correspond to the respective qualifier signal being input to the first circuit 510.

To receive the first internal signal in this example, the input 312 of the first modulator 310 may be coupled to the input 512 of the first circuit 510, as shown in FIG. 5. In this example, the first internal signal indicates the timing of the first event at the first circuit 510. For example, if the first internal signal includes the respective enable signal and the respective enable signal enables the first circuit 510 when the respective enable signal is high, then the timing of the first event (i.e., enablement of the first circuit 510 in this example) may be indicated by a rising edge in the respective enable signal. However, the enable signal is not limited to this example. In general, the first event (i.e., enablement of the first circuit 510 in this example) may be indicated by an edge in the enable signal that corresponds to a transition from a first logic state to a second logic state, wherein the first circuit 510 is enabled by the first enable signal when the first enable signal is at the second logic state and disabled by the first enable signal when the first enable signal is at the first logic state. The first logic state may be zero and the second logic state may be one, or vice versa.

In the example shown in FIG. 5, the second circuit 520 has an input 522 configured to receive the second internal signal. The second internal signal may include a respective enable signal for selectively enabling the second circuit 520, a respective qualifier signal, or another type of signal. For the example of the respective enable signal, the second event may correspond to enablement of the second circuit 520. For the example of the respective qualifier signal, the second event may correspond to the respective qualifier signal being input to the second circuit 520.

To receive the second internal signal in this example, the input 322 of the second modulator 320 may be coupled to the input 522 of the second circuit 520, as shown in FIG. 5. In this example, the second internal signal indicates the timing of the second event at the second circuit 520. For example, if the second internal signal includes the respective enable signal and the respective enable signal enables the second circuit 520 when the respective enable signal is high, then the timing of the second event (i.e., enablement of the second circuit 520 in this example) may be indicated by a rising edge in the respective enable signal.

In the example shown in FIG. 5, the third circuit 530 has an input 532 configured to receive the third internal signal. The third internal signal may include a respective enable signal for selectively enabling the third circuit 530, a respective qualifier signal, or another type of signal. For the example of the respective enable signal, the third event may correspond to enablement of the third circuit 530.

To receive the third internal signal in this example, the input 332 of the third modulator 330 may be coupled to the input 532 of the third circuit 530, as shown in FIG. 5. In this example, the third internal signal indicates the timing of the third event at the third circuit 530. For example, if the third internal signal includes the respective enable signal and the respective enable signal enables the third circuit 530 when the respective enable signal is high, then the timing of the third event (i.e., enablement of the third circuit 530 in this example) may be indicated by a rising edge in the respective enable signal.

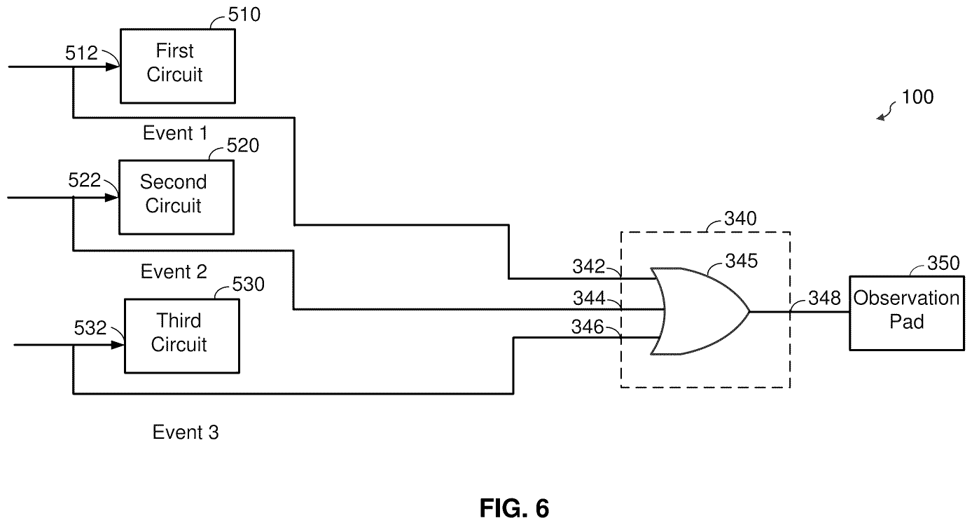

In certain aspects, each of the first internal signal, the second internal signal, and the third internal signal may already have a unique profile. In this example, the unique profiles of the internal signals allow the internal signals to be distinguished from one another in the merged output signal without the modulators 310, 320, and 330. Thus, in this example, the modulators 310, 320, and 330 may be omitted. In this regard, FIG. 6 shows an example in which the modulators 310, 320, and 330 are omitted. In this example, the first internal signal is input to the first input 342 of the merge circuit 340, the second internal signal is input to the second input 344 of the merge circuit 340, and the third internal signal is input to the third input 346 of the merge circuit 340. For the example where the events being observed correspond to the events at the circuits 510, 520, and 530, the first input 342 of the merge circuit 340 is coupled to the input 512 of the first circuit 510 to receive the first internal signal, the second input 344 of the merge circuit 340 is coupled to the input 522 of the second circuit 520 to receive the second internal signal, and the third input 346 of the merge circuit 340 is coupled to the input 532 of the third circuit 530 to receive the third internal signal.

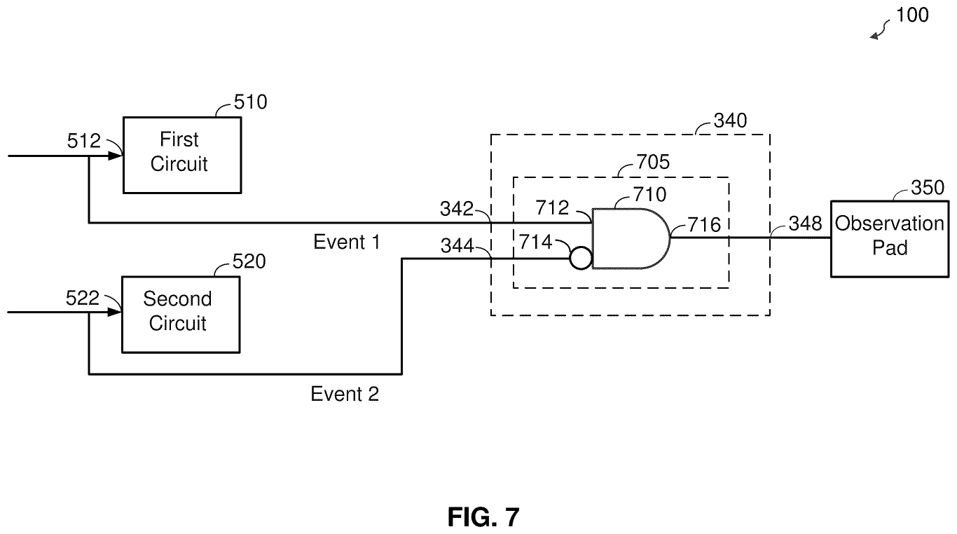

FIG. 7 shows an example in which the merge circuit 340 includes a pulse generator 705 configured to generate a pulse indicating a timing gap between the first event and the second event according to certain aspects. In this example, the first event is indicated by a first edge (e.g., rising edge) in the first internal signal and the second event is indicated by a second edge (i.e., rising edge) in the second internal signal. The pulse generator 705 is configured to receive the first internal signal and the second internal signal, generate a pulse having a pulse width approximately equal to a timing gap between the first edge in the first internal signal and the second edge in the second internal signal, and output the pulse to the observation pad 350. In this example, the timing gap between the first event and the second event may be determined by measuring the width of the pulse output from the observation pad 350. In certain aspects, the pulse generator 705 may be coupled to the input 512 of the first circuit 510 to receive the first internal signal and coupled to the input 522 of the second circuit 520 to receive the second internal signal.

In the example shown in FIG. 7, the pulse generator 705 includes an AND gate 710 having a non-inverting input 712, an inverting input 714, and an output 716. The non-inverting input 712 is configured to receive the first internal signal and may be coupled to the input 512 of the first circuit 510. The inverting input 714 is configured to receive the second internal signal and may be coupled to the input 522 of the second circuit 520. The output 716 is coupled to the observation pad 350. It is to be appreciated that the AND gate 710 may be implemented on the chip 100 using a combination of logic gates including one or more inverters, one or more NOR gates, and/or one or more NAND gates.

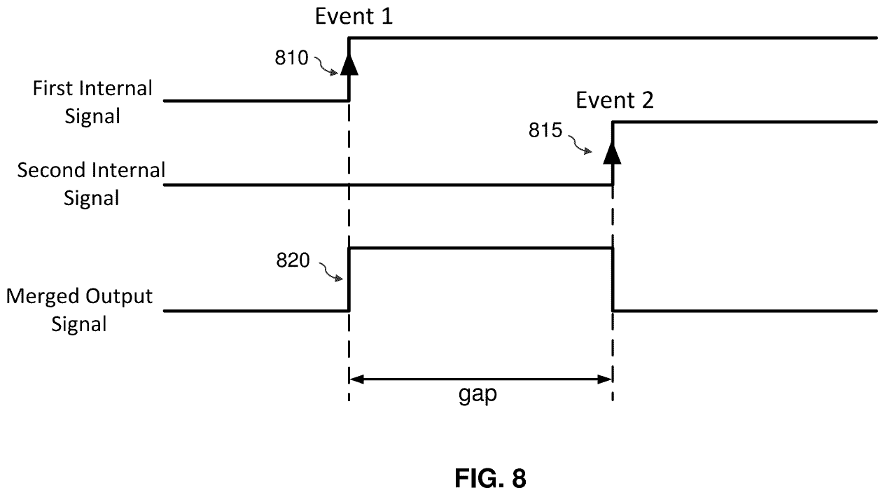

Exemplary operations of the pulse generator 705 will now be discussed with reference to FIG. 8. FIG. 8 shows a timing diagram illustrating an example of the first internal signal, the second internal signal, and the merged output signal. In the example in FIG. 8, the first edge of the first internal signal is a rising edge 810 indicating the first event. For example, the first internal signal may be an enable signal in which the rising edge 810 indicates enablement of the first circuit 510. Also, in the example in FIG. 8, the second edge of the second internal signal is a rising edge 815 indicating the second event. For example, the second internal signal may be another enable signal in which the rising edge 815 indicates enablement of the second circuit 520. However, it is to be appreciated that the present disclosure is not limited to this example.

In this example, the pulse generator 705 generates a pulse 820 having a width that is approximately equal to the timing gap between the first edge (i.e., rising edge 810 in this example) and the second edge (i.e., rising edge 815 in this example). Since the first edge indicates the first event and the second edge indicates the second event, the width of the pulse 820 is approximately equal to the timing gap between the first event and the second event. As a result, the timing gap between the first event and the second event may be determined by measuring the width of the pulse 820 output from the observation pad 350. Thus, in this example, the pulse may be used to measure the timing gap between the first event and the second event (e.g., to check for compliance with a minimum timing gap in a timing specification).

The exemplary implementation of the pulse generator 705 shown in FIG. 7 may also be used to ensure that the first event and the second event occur in the proper order (i.e., sequence) in which the second event occurs after the first event. This is because, in this example, the pulse generator 705 does not generate the pulse when the second edge (which indicates the second event) arrives at the pulse generator 705 before the first edge (which indicates the first event). Thus, an absence of the pulse indicates that the first event and the second event do not occur in the proper order.

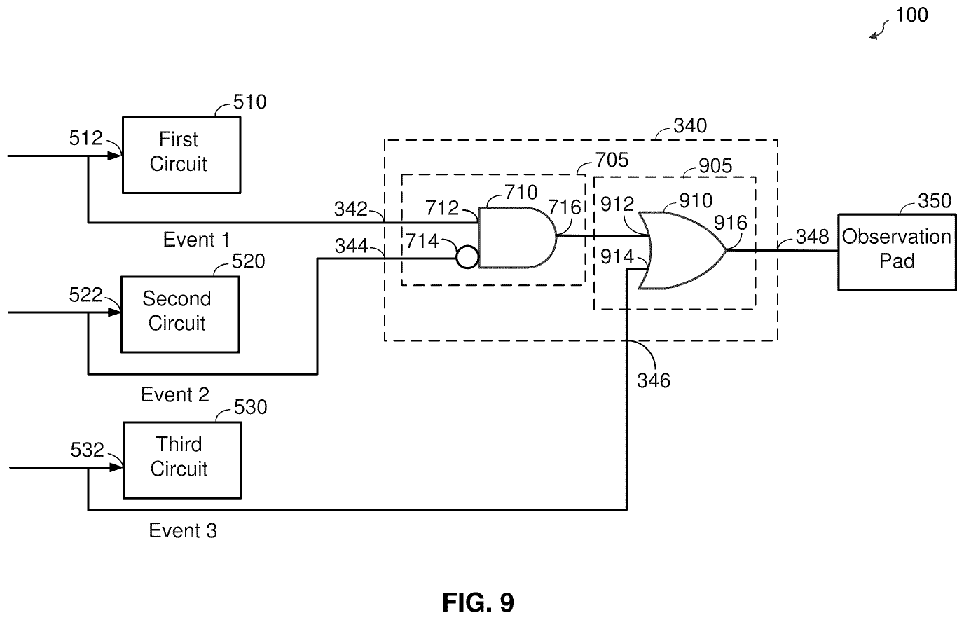

FIG. 9 shows an example in which the merge circuit 340 includes merge logic 905 configured to merge the third internal signal with the pulse from the pulse generator 705 to generate the merged output signal. In the example in FIG. 9, the merge logic includes an OR gate 910 having a first input 912, a second input 914, and an output 916. The first input 912 is coupled to the output of the pulse generator 705 (e.g., output 716 of the AND gate 710), the second input 914 is coupled to the third input 346 of the merge circuit 340 to receive the third internal signal, and the output 916 is coupled to the observation pad 350. In this example, the OR gate 910 performs an OR operation to merge the pulse from the pulse generator 705 and the third internal signal into the merged output signal. However, it is to be appreciated that the merge logic 905 is not limited to the OR gate 910, and that the merge logic 905 may include another type of logic gate or a combination of logic gates configured to merge the third internal signal with the pulse from the pulse generator 705.

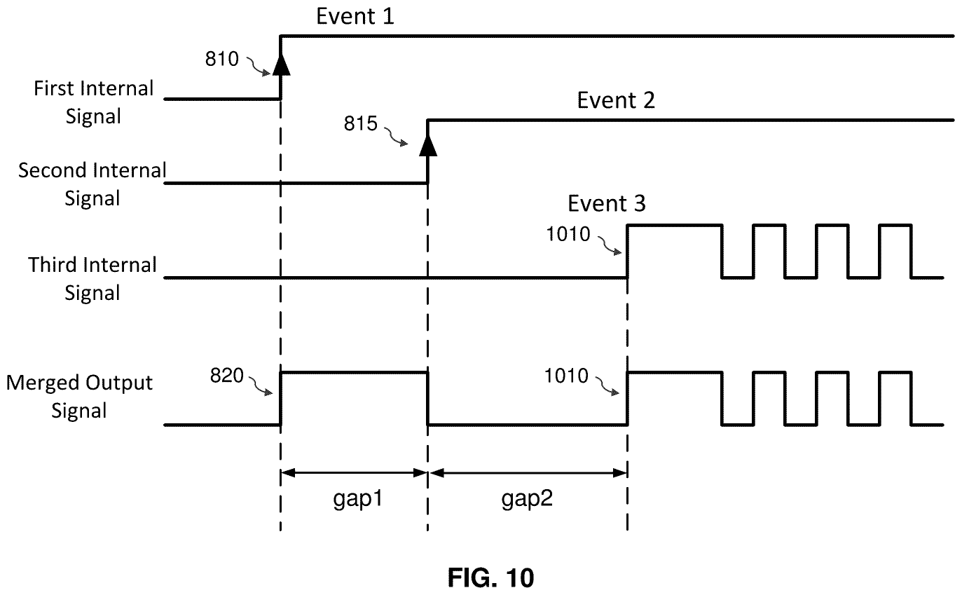

Exemplary operations of the merge circuit 340 will now be discussed with reference to FIG. 10. FIG. 10 shows a timing diagram illustrating an example of the first internal signal, the second internal signal, the third internal signal, and the merged output signal. In the example in FIG. 10, the rising edge 810 of the first internal signal indicates the first event and the rising edge 815 of the second internal signal indicates the second event. Also, in the example in FIG. 10, the third internal signal has a pattern (e.g., sequence of pulses) in which the rising edge 1010 of the first pulse in the pattern indicates the third event. In this example, the third event may correspond to the arrival of the pattern at the third circuit 530. Note that the pattern in this example is part of the third internal signal and is not generated by the third modulator 330 discussed above.

In the example shown in FIG. 10, the merged output signal includes the pulse 820 and the pattern of the third internal signal. In this example, the width of the pulse 820 indicates the timing gap (labeled “gap1”) between the first event and the second event. The timing gap between the end of the pulse 820 (e.g., falling edge of the pulse 820) and the rising edge 1010 of the first pulse in the pattern indicates the timing gap (labeled “gap2”) between the second event and the third event.

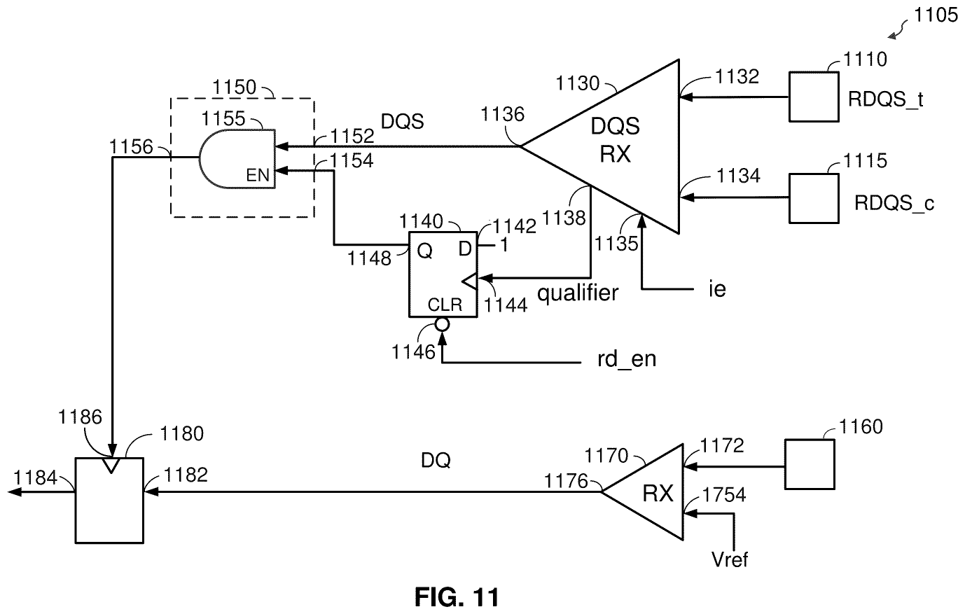

Aspects of the present disclosure may be used, for example, in a memory interface to check whether internal signals in the memory interface meet a timing specification. In this regard, FIG. 11 shows an example of a memory interface 1105 in which aspects of the present disclosure may be used. The memory interface 1105 may be integrated on the chip 100.

The memory interface 1105 may be configured to interface a memory controller (not shown) with a memory device (not shown) located on another chip. In this example, the memory interface 1105 may also be referred to as a physical layer (PHY) circuit or another term. The memory device may include synchronous dynamic random-access memory (SDRAM) or another type of memory.

In this example, the memory interface 1105 includes a first pad 1110, a second pad 1115, and a third pad 1160 on the chip 100. The memory interface 1105 also includes a data strobe receiver 1130, a flip-flop 1140, a gating circuit 1150, a data receiver 1170, and a data capture circuit 1180. In this example, the memory interface 1105 is configured to receive a differential data strobe signal from the memory device. The differential data strobe signal includes a first strobe signal RDQS_t received on the first pad 1110 and a second strobe signal RDQS_c received on the second pad 1115. The memory interface 1105 is also configured to receive a data signal from the memory device on the third pad 1160. As discussed further below, the memory interface 1105 uses the differential data strobe signal to generate a data strobe signal DQS for timing the capture of data bits from the data signal.

The data strobe receiver 1130 includes a first input 1132, a second input 1134, an enable input 1135, a first output 1136, and a second output 1138. The first input 1132 is coupled to the first pad 1110 to receive the first strobe signal RDQS_t and the second input 1134 is coupled to the second pad 1115 to receive the second strobe signal RDQS_c. The first output 1136 is coupled to a first input 1152 of the gating circuit 1150. The enable input 1135 is configured to receive a first enable signal (labeled “ie” for input enable) for selectively enabling the data strobe receiver 1130.

During a read operation, the data strobe receiver 1130 is configured to generate the data strobe signal DQS and a qualifier signal based on the first strobe signal RDQS_t and the second strobe signal RDQS_c. For example, the data strobe receiver 1130 may output a one for the data strobe signal DQS when the first strobe signal RDQS_t is greater than the second strobe signal RDQS_c and output a zero for the data strobe signal DQS when the first strobe signal RDQS_t is less than the second strobe signal RDQS_c. The data strobe receiver 1130 may output a one for the qualifier signal when the second strobe signal RDQS_c is greater than a reference voltage and output a zero for the qualifier signal when the second strobe signal RDQS_c is less than the reference voltage. The data strobe receiver 1130 outputs the data strobe signal DQS at the first output 1136 and outputs the qualifier signal at the second output 1138.

The flip-flop 1140 has a signal input 1142 (labeled “D”), a clock input 1144, an enable input 1146, and an output 1148 (labeled “Q”). The clock input 1144 may be non-inverting or inverting. In this example, the signal input 1142 is coupled to a logic value of one (e.g., a supply voltage), the clock input 1144 is coupled to the second output 1138 of the data strobe receiver 1130, and the output 1148 is coupled to a second input 1154 of the gating circuit 1150. The enable input 1146 is configured to receive a second enable signal (labeled “rd_en” for read enable).

In the example shown in FIG. 11, the enable input 1146 corresponds to an inverting clear input (labeled “CLR”) of the flip-flop 1140. In this example, the flip-flop 1140 is configured to keep the output 1148 at logic zero (i.e., low state) when the second enable signal is logic zero (i.e., low) and enable the flip-flop 1140 when the second enable signal is logic one (i.e., high). However, it is to be appreciated that the present disclosure is not limited to this example.

When enabled, the flip-flop 1140 is configured to generate a gating signal at the output 1148 based on the logic one at the signal input 1142 and the qualifier signal at the clock input 1144. When the flip-flop 1140 is disabled (e.g., in the clear state), the gating signal is kept low. Although one flip-flop (i.e., the flip-flop 1140) is shown in the example in FIG. 11, it is to be appreciated that, in some implementations, the memory interface 1105 may include one or more additional flip-flops that are cascaded with the flip-flop 1140 between the data strobe receiver 1130 and the second input 1154 of the gating circuit 1150. The one or more additional flip-flops may be clocked by the data strobe signal DQS.

The gating circuit 1150 is configured to receive the data strobe signal DQS from the data strobe receiver 1130 at the first input 1152 and receive the gating signal from the flip-flop 1140 at the second input 1154. The gating circuit 1150 may be configured to gate (i.e., block) the data strobe signal DQS when the gating signal is logic zero (i.e., low) and pass the data strobe signal DQS to an output 1156 of the gating circuit 1150 when the gating signal is logic one (i.e., high). The gating signal may be used to filter output a preamble in the data strobe signal DQS at the start of a read operation.

In the example shown in FIG. 11, the gating circuit 1150 is implemented with an AND gate 1155. However, it is to be appreciated that the gating circuit 1150 is not limited to an AND gate, and that the gating circuit 1150 may be implemented with another type of logic gate, combinational logic, a multiplexer, one or more switches, or any combination thereof.

The data receiver 1170 has a first input 1172, a second input 1754, and an output 1176. The first input 1172 is coupled to the third pad 1160 to receive the data signal, and the second input 1174 is coupled to a reference voltage (labeled “Vref”). The reference voltage may be the same as or different from the reference voltage used by the data strobe receiver 1130 to generate the qualifier signal. The data receiver 1170 is configured to generate an internal data signal DQ based on the received data signal and the reference voltage. For example, the data signal DQ may be high when the received data signal is greater than the reference voltage and the data signal DQ may be low when the received data signal is less than the reference voltage.

The capture circuit 1180 has a data input 1182, a clock input 1186, and an output 1184. The data input 1182 is coupled to the output 1176 of the data receiver 1170 to receive the data signal DQ. The clock input 1186 is coupled to the output 1156 of the gating circuit 1150 to receive the data strobe signal DQS. The output 1184 may be coupled to the memory controller (not shown). The capture circuit 1180 is configured to capture (i.e., sample) data bits from the data signal DQ on edges (e.g., rising edges and/or falling edges) of the data strobe signal DQS, and output the data bits at the output 1184.

During a read operation, the memory interface 1105 may receive a burst of data bits in the data signal received from the memory device (not shown). To prepare for the burst of data bits, the data strobe receiver 1130 and the flip-flop 1140 may be sequentially enabled using the first enable signal (labeled “ie”) and the second enable signal (labeled “rd_en”), respectively. For example, the data strobe receiver 1130 may be enabled first followed by the flip-flop 1140.

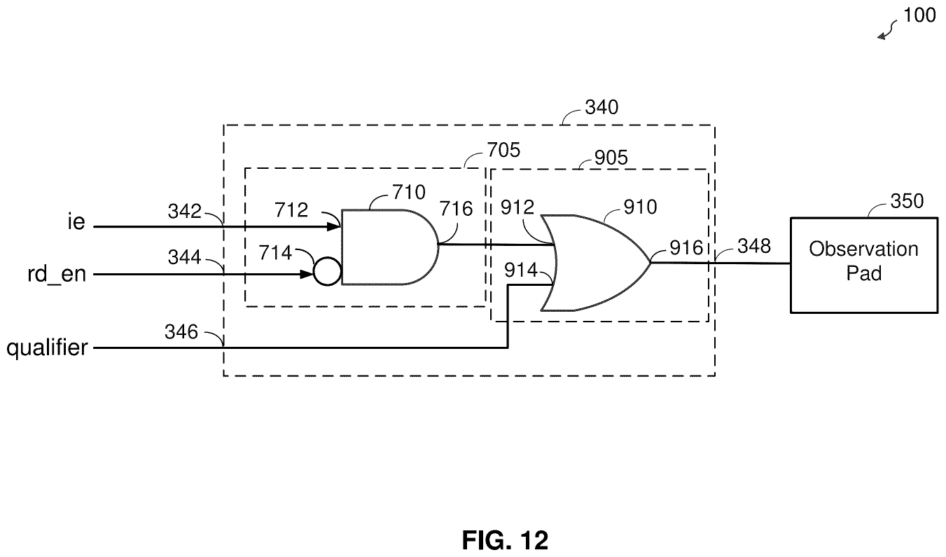

In this example, the timing gap between the enablement of the data strobe receiver 1130 and the enablement of the flip-flop 1140 may need to meet a timing specification (i.e., meet a minimum timing gap in the specification). Also, the timing gap between the qualifier signal and the enablement of the flip-flop 1140 may need to meet the timing specification. In this regard, FIG. 12 shows an example in which the merge circuit 340 and the observation pad 350 are used to monitor the enablement of the data strobe receiver 1130, the enablement of the flip-flop 1140, and the qualifier signal to check for compliance with the timing specification. In this example, the first input 342 of the merge circuit 340 is coupled to the enable input 1135 of the data strobe receiver 1130 (shown in FIG. 11) to receive the first enable signal (labeled “ie”). The second input 344 of the merge circuit 340 is coupled to the enable input 1146 of the flip-flop 1140 (shown in FIG. 11) to receive the second enable signal (labeled “rd_en”). The third input 346 of the merge circuit 340 is coupled to the second output 1138 of the data strobe receiver 1130 (shown in FIG. 11) to receive the qualifier signal.

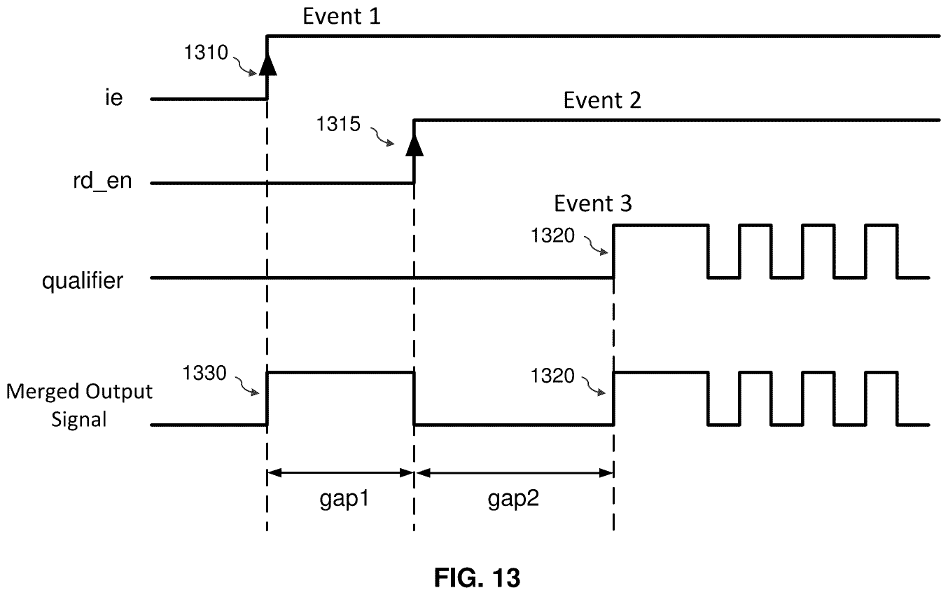

FIG. 13 shows a timing diagram illustrating an example in which the merged output signal may be used to check whether the memory interface 1105 complies with the timing specification. The check may be performed, for example, by an external test system (not shown) coupled to the observation pad 350, as discussed above.

In this example, the first event correspond to enablement of the data strobe receiver 1130, the second event corresponds to enablement of the flip-flop 1140, and the third event corresponds to the qualifier signal. In the example in FIG. 13, the first enable signal (labeled “ie”) has a rising edge 1310 indicating enablement of the data strobe receiver 1130 and the second enable signal (labeled “rd_en”) has a rising edge 1315 indicating enablement of the flip-flop 1140.

In this example, the pulse generator 705 generates a pulse 1330 having a width approximately equal to the timing gap between the rising edge 1310 of the first enable signal and the rising edge 1315 of the second enable signal. Since the rising edge 1310 of the first enable signal indicates enablement of the data strobe receiver 1130 and the rising edge 1315 of the second enable signal indicates enablement of the flip-flop 1140, the width of the pulse 1330 indicates the timing gap (labeled “gap1”) between the enablement of the data strobe receiver 1130 and the enablement of the flip-flop 1140. Thus, the width of the pulse 1330 may be used to check whether the timing gap between the enablement of the data strobe receiver 1130 and the enablement of the flip-flop 1140 meets the timing specification (i.e., meets a minimum timing gap in the specification).

In the example in FIG. 13, the merged output signal also includes the qualifier signal. In this example, the timing gap between the enablement of the flip-flop 1140 and the qualifier signal may be determined based on the timing gap (labeled “gap2”) between the end of the pulse 1330 (e.g., falling edge of the pulse 1330) and the first rising edge 1320 of the qualifier signal. Thus, the timing gap between the pulse 1330 and the qualifier signal may be used to check compliance with the timing specification. For example, the timing gap between the pulse 1330 and the qualifier signal may be compared with a minimum timing gap in the timing specification. In this example, the timing specification is met when the timing gap between the pulse 1330 and the qualifier signal is greater than the minimum timing gap. However, it is to be appreciated that the present disclosure is not limited to this example.

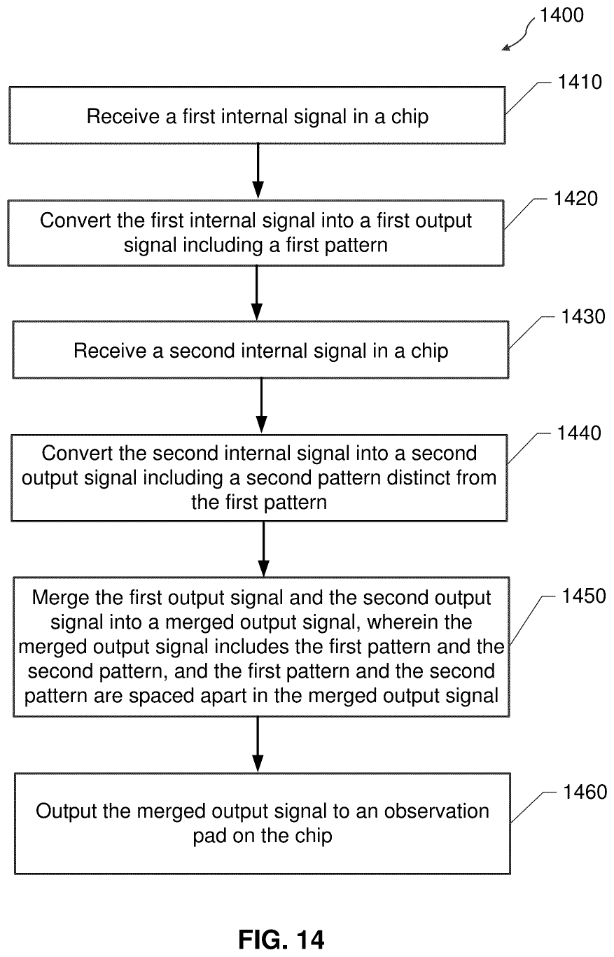

FIG. 14 illustrates a method 1400 for signal monitoring according to certain aspects of the present disclosure.

At block 1410, a first internal signal in a chip is received. For example, the first internal signal may be received by the first modulator 310. In one example, the first internal signal includes a first enable signal for selectively enabling a first circuit (e.g., the first circuit 510) on the chip.

At block 1420, the first internal signal is converted into a first output signal including a first pattern. For example, the first modulator 310 may convert the first internal signal into the first output signal.

At block 1430, a second internal signal in the chip is received. For example, the second internal signal may be received by the second modulator 320. In one example, the second internal signal includes a second enable signal for selectively enabling a second circuit (e.g., the second circuit 520) on the chip.

At block 1440, the second internal signal is converted into a second output signal including a second pattern distinct from the first pattern. For example, the second modulator 320 may convert the second internal signal into the second output signal.

At block 1450, the first output signal and the second output signal are merged into a merged output signal, wherein the merged output signal includes the first pattern and the second pattern, and the first pattern and the second pattern are spaced apart in the merged output signal. For example, the merge circuit 340 may merge the first output signal and the second output signal.

At block 1460, the merged output signal is output to an observation pad on the chip. The observation pad may correspond to the observation pad 350.

Implementation examples are described in the following numbered clauses:

1. A chip, comprising:
a first modulator configured to receive a first internal signal, and convert the first internal signal into a first output signal including a first pattern;
a second modulator configured to receive a second internal signal, and convert the second internal signal into a second output signal including a second pattern distinct from the first pattern;
an observation pad; and
a merge circuit coupled to the observation pad, wherein the merge circuit is configured to merge the first output signal and the second output signal into a merged output signal, and output the merged output signal to the observation pad, wherein the merged output signal includes the first pattern and the second pattern, and the first pattern and the second pattern are spaced apart in the merged output signal.

2. The chip of clause 1, wherein the first internal signal comprises a first enable signal for selectively enabling a first circuit on the chip.

3. The chip of clause 2, wherein the second internal signal comprises a second enable signal for selectively enabling a second circuit on the chip.

4. The chip of any one of clauses 1 to 3, further comprising a third modulator configured to receive a third internal signal, and convert the third internal signal into a third output signal including a third pattern distinct from the first pattern and the second pattern, wherein the merge circuit is configured to merge the first output signal, the second output signal, and the third output signal into the merged output signal.

5. The chip of clause 4, wherein the merged output signal includes the first pattern, the second pattern, and the third pattern, and the first pattern, the second pattern, and the third pattern are spaced apart in the merged output signal, and further wherein a length of the first pattern is less than a timing gap between a beginning of the first pattern and a beginning of the second pattern, and a length of the second pattern is less than a timing gap between the beginning of the second pattern and a beginning of the third pattern.

6. The chip of any one of clauses 1 to 5, wherein the first pattern comprises a first sequence of ones and zeros, and the second pattern comprises a second sequence of ones and zeros distinct from the first sequence of ones and zeros.

7. The chip of any one of clauses 1 to 6, wherein the first modulator is configured to convert a first edge in the first internal signal into the first pattern, and convert a second edge in the second internal signal into the second pattern.

8. The chip of clause 7, wherein the first internal signal comprises an enable signal for selectively enabling a circuit on the chip, the first edge comprises a transition from a first logic state to a second logic state, and the circuit is enabled by the enable signal when the enable signal is at the second logic state and the circuit is disabled by the enable signal when the enable signal is at the first logic state.

9. The chip of clause 7 or 8, wherein the first edge comprises a first rising edge and the second edge comprises a second rising edge.

10. The chip of any one of clauses 1 to 9, wherein the merge circuit comprises an OR gate.

11. A chip, comprising:
an observation pad; and
a merge circuit coupled to the observation pad, wherein the merge circuit comprises:
a pulse generator configured to receive a first internal signal and a second internal signal, and generate a pulse having a width approximately equal to a timing gap between a first edge in the first internal signal and a second edge in the second internal signal.

12. The chip of clause 11, wherein the first internal signal comprises a first enable signal for selectively enabling a first circuit on the chip.

13. The chip of clause 12, wherein the second internal signal comprises a second enable signal for selectively enabling a second circuit on the chip.

14. The chip of any one of clauses 11 to 13, wherein the first edge comprises a first rising edge and the second edge comprises a second rising edge.

15. The chip of any one of clauses 11 to 14, wherein the merge circuit further comprises merge logic configured to receive a third internal signal and the pulse, merge the third internal signal with the pulse into a merged output signal, and output the merged output signal to the observation pad.

16. The chip of clause 15, wherein the merge logic comprises an OR gate.

17. The chip of clause 15 or 16, wherein the first internal signal comprises a first enable signal for selectively enabling a first circuit on the chip.

18. The chip of clause 17, wherein the second internal signal comprises a second enable signal for selectively enabling a second circuit on the chip.

19. The chip of clause 17 or 18, wherein the first circuit comprises a receiver, and the third internal signal comprises a qualifier signal output from the receiver.

20. The chip of clause 19, wherein the receiver is configured to receive a first strobe signal and a second strobe signal, generate a data strobe signal based on the first strobe signal and the second strobe signal, and generate the qualifier signal based on the second strobe signal and a reference voltage.

21. The chip of any one of clauses 11 to 20, wherein the pulse generator comprises an AND gate.

22. The chip of clause 21, wherein the AND gate has a non-inverting input, an inverting input, and an output, and wherein the non-inverting input is configured to receive the first internal signal, the inverting input is configured to receive the second internal signal, and the output is configured to output the pulse.

23. A method for signal monitoring, comprising:
receiving a first internal signal in a chip;
converting the first internal signal into a first output signal including a first pattern;
receiving a second internal signal in the chip;
converting the second internal signal into a second output signal including a second pattern distinct from the first pattern;
merging the first output signal and the second output signal into a merged output signal, wherein the merged output signal includes the first pattern and the second pattern, and the first pattern and the second pattern are spaced apart in the merged output signal; and
outputting the merged output signal to an observation pad on the chip.

24. The method of clause 23, wherein the first internal signal comprises a first enable signal for selectively enabling a first circuit on the chip.

25. The method of clause 24, wherein the second internal signal comprises a second enable signal for selectively enabling a second circuit on the chip.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. As used herein, “approximately” means within 90 percent to 110 percent of the stated value.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first modulator configured to receive a first internal signal, and convert the first internal signal into a first output signal including a first pattern;
a second modulator configured to receive a second internal signal, and convert the second internal signal into a second output signal including a second pattern distinct from the first pattern;
an observation pad; and
a merge circuit coupled to the observation pad, wherein the merge circuit is configured to merge the first output signal and the second output signal into a merged output signal, and output the merged output signal to the observation pad, wherein the merged output signal includes the first pattern and the second pattern, and the first pattern and the second pattern are spaced apart in the merged output signal.

2. The chip of claim 1, wherein the first internal signal comprises a first enable signal for selectively enabling a first circuit on the chip.

3. The chip of claim 2, wherein the second internal signal comprises a second enable signal for selectively enabling a second circuit on the chip.

4. The chip of claim 1, further comprising a third modulator configured to receive a third internal signal, and convert the third internal signal into a third output signal including a third pattern distinct from the first pattern and the second pattern, wherein the merge circuit is configured to merge the first output signal, the second output signal, and the third output signal into the merged output signal.

5. The chip of claim 4, wherein the merged output signal includes the first pattern, the second pattern, and the third pattern, and the first pattern, the second pattern, and the third pattern are spaced apart in the merged output signal, and further wherein a length of the first pattern is less than a timing gap between a beginning of the first pattern and a beginning of the second pattern, and a length of the second pattern is less than a timing gap between the beginning of the second pattern and a beginning of the third pattern.

6. The chip of claim 1, wherein the first pattern comprises a first sequence of ones and zeros, and the second pattern comprises a second sequence of ones and zeros distinct from the first sequence of ones and zeros.

7. The chip of claim 1, wherein the first modulator is configured to convert a first edge in the first internal signal into the first pattern, and convert a second edge in the second internal signal into the second pattern.

8. The chip of claim 7, wherein the first internal signal comprises an enable signal for selectively enabling a circuit on the chip, the first edge comprises a transition from a first logic state to a second logic state, and the circuit is enabled by the enable signal when the enable signal is at the second logic state and the circuit is disabled by the enable signal when the enable signal is at the first logic state.

9. The chip of claim 1, wherein the merge circuit comprises an OR gate.

10. A chip, comprising:
an observation pad; and
a merge circuit coupled to the observation pad, wherein the merge circuit comprises:
a pulse generator configured to receive a first internal signal and a second internal signal, and generate a pulse having a width approximately equal to a timing gap between a first edge in the first internal signal and a second edge in the second internal signal.

11. The chip of claim 10, wherein the first internal signal comprises a first enable signal for selectively enabling a first circuit on the chip.

12. The chip of claim 11, wherein the second internal signal comprises a second enable signal for selectively enabling a second circuit on the chip.

13. The chip of claim 10, wherein the merge circuit further comprises merge logic configured to receive a third internal signal and the pulse, merge the third internal signal with the pulse into a merged output signal, and output the merged output signal to the observation pad.

14. The chip of claim 13, wherein the merge logic comprises an OR gate.

15. The chip of claim 13, wherein the first internal signal comprises a first enable signal for selectively enabling a first circuit on the chip.

16. The chip of claim 15, wherein the second internal signal comprises a second enable signal for selectively enabling a second circuit on the chip.

17. The chip of claim 15, wherein the first circuit comprises a receiver, and the third internal signal comprises a qualifier signal output from the receiver.

18. The chip of claim 17, wherein the receiver is configured to receive a first strobe signal and a second strobe signal, generate a data strobe signal based on the first strobe signal and the second strobe signal, and generate the qualifier signal based on the second strobe signal and a reference voltage.

19. The chip of claim 10, wherein the pulse generator comprises an AND gate.

20. A method for signal monitoring, comprising:
receiving a first internal signal in a chip;
converting the first internal signal into a first output signal including a first pattern;
receiving a second internal signal in the chip;
converting the second internal signal into a second output signal including a second pattern distinct from the first pattern;
merging the first output signal and the second output signal into a merged output signal, wherein the merged output signal includes the first pattern and the second pattern, and the first pattern and the second pattern are spaced apart in the merged output signal; and
outputting the merged output signal to an observation pad on the chip.
